(19) United States
(12) Patent Application Publication
(10) Pub. No.: US 2016/0379919 A1
(43) Pub. Date: Dec. 29, 2016

(54) Electronic device and method of manufacturing the same

(71) Applicant: Infineon Technologies Austria AG, Villach (AT)

(72) Inventors: Ralf OTREMBA, Kaufbeuren (DE); Ulrich FROEHLER, Nersingen (DE); Felix GRAWERT, Villach (AT)

(21) Appl. No.: 15/187,818

(22) Filed: Jun. 21, 2016

(30) Foreign Application Priority Data
Jun. 23, 2015 (DE) 10 2015 110078.9

(51) Int. Cl. H01L 23/495; H01L 21/48

(52) U.S. Cl. CPC H01L 23/49568; H01L 23/49503; H01L 23/4952; H01L 23/49562; H01L 21/4825; H01L 21/4882

(57) ABSTRACT

Various embodiments provide an electronic device, wherein the electronic device comprises a carrier body; a plurality of pins, a die comprising a switched terminal; wherein the switched terminal is attached onto and electrically connected to one of the plurality of pins; and wherein the die is configured in such a way that the switched terminal is electrically connected to a high electrical potential.

### TECHNICAL FIELD

Various embodiments relate to an electronic device, in particular an electronic device comprising a switching element, and to a method of manufacturing an electronic device.

### BACKGROUND

In the field of electronic devices (e.g. power devices for the automotive field) often parasitic capacities are of detrimental effect in particular in case of high frequency devices. In case of increasing switching frequencies of the electronic devices the losses increase due to the parasitic capacity.

### SUMMARY

Various embodiments provide an electronic device, wherein the electronic device comprises a carrier body; a plurality of pins, a die comprising a switched terminal; wherein the switched terminal is attached onto and electrically connected to one of the plurality of pins; and wherein the die is configured in such a way that the switched terminal is electrically connected to a high electrical potential.

Furthermore, various embodiments provide an electronic device, wherein the electronic device comprises a field effect transistor comprising a drain terminal; a lead frame comprising a die pad and a plurality of leads; wherein the drain terminal is electrically connected to and attached onto at least one of the plurality of leads.

Moreover, various embodiments provide a method of manufacturing an electronic device, wherein the method comprises providing a carrier comprising a carrier body and a plurality of pins; attaching and electrically connecting a die comprising a switched terminal onto one of the plurality of pins, wherein the attaching is performed in such a way that a high electrical potential is connectable to the switched terminal.

### BRIEF DESCRIPTION OF THE DRAWINGS

In the drawings, like reference characters generally refer to the same parts throughout the different views. The drawings are not necessarily to scale. Instead emphasis is generally being placed upon illustrating the principles of the invention. In the following description, various embodiments are described with reference to the following drawings, in which:

FIGS. 1A and 1B schematically show an electronic device according to an exemplary embodiment;

FIG. 2 schematically shows a detail of an electronic device according to an exemplary embodiment;

FIG. 3 illustrates a flowchart of a method of reducing a sheet resistance in an electronic device according to an exemplary embodiment.

### DETAILED DESCRIPTION

In the following further exemplary embodiments of an electronic device and method of manufacturing an electronic device are described. It should be noted that the description of specific features described in the context of one specific exemplary embodiment may be combined with others exemplary embodiments as well.

The word “exemplary” is used herein to mean “serving as an example, instance, or illustration”. Any embodiment or design described herein as “exemplary” is not necessarily to be construed as preferred or advantageous over other embodiments or designs.

Various exemplary embodiments provide an electronic device comprising a carrier (like a lead frame, for example) comprising a carrier body (like a die pad, for example) and a plurality of pins (like leads of a lead frame); and further comprising a power die mounted onto one of the plurality of pins, wherein the one of the plurality of pins is configured to be electrically connected to a high potential (in general to a high positive potential and not to ground potential). It should be noted that in case that the carrier body and/or pins are part of a lead frame, the leads or pins of the lead frame may be electrically disconnected from the die pad.

Various exemplary embodiments provide an electronic arrangement comprising an electronic device according to an exemplary embodiment and a mounting structure, wherein the carrier body is mounted to the mounting structure and/or the one of the plurality of pins is connectable to a power source. In particular, the electronic arrangement comprises a power source connected to the one pin. It should be noted that the carrier body may be directly or indirectly mounted on the mounting structure, e.g. a plate or the like. Furthermore, it should be noted that the carrier body may directly contact the mounting structure or may be covered by an encapsulation.

The term “high electrical potential” or “high potential” may particularly denote the potential which is different to mass independent whether it is (generally) a positive high potential, e.g. between 100 V and 800 V, e.g. about 400 V, or sometimes a negative high potential, e.g. between −100 V and −800 V, e.g. about −400 V. That is, configured to be connected to a “high potential” may particularly denote an element or terminal which is configured and intended to be connected to an electrical potential having a high absolute value and thus being different to the mass or ground potential.

In particular, the carrier body and the plurality of pins may be formed by a lead frame comprising a die pad (carrier body) and the plurality of pins may form the leads of the lead frame. In particular, the die may be a power die or chip, e.g. a (power) transistor or a diode, like a CoolMOS, IGBT, SiC-MOSFET or -diode. In the case of a field effect transistor the switched terminal attached to the pin may be the drain terminal of the transistor. In particular, the one of the plurality of pins may be formed or configured as a drain pin or drain contact.

In particular, the die may be attached or mounted directly onto the pin, e.g. a lead of a lead frame or the like.

By attaching the die to a pin via or by a switched terminal configured or intended to be connected to a high electrical potential (e.g. a drain terminal or contact) it may be possible to reduce the losses due to parasitic capacities. For example, the parasitic capacity may be reduced due to the reduction of the area of the one pin compared to the carrier body.

According to an exemplary embodiment of the electronic device the carrier body is part of a lead frame comprising a die pad and a plurality of leads, wherein the pins are formed by the plurality of leads and the carrier body is formed by the die pad.

In particular, the one pin (or lead) may be disconnected or isolated from the carrier body, e.g. may be a lead of the lead frame cut or separated (and thus isolated) from the carrier body. It should be noted that the carrier body may directly connected to a further pin or the carrier body and a further pin may be integrally formed.

According to an exemplary embodiment of the electronic device the carrier body and the plurality of pins are arranged on different levels.

In particular, the plurality of pins, e.g. leads of a lead frame, may be arranged on one level or in one plane, while the carrier body, e.g. a die pad, may be arranged on another level or plane. For example, the level the plurality of pins are arranged in may be 0.5 mm to 2.5 mm, e.g. about 1 mm, above the level of the carrier body or die pad. That is, a distance between a middle of the carrier body plane and a middle of the pins may define the difference of the two levels. In particular, by arranging the plurality of pins on a different level it may be possible that a distance between the pin level and a substrate or board the electronic device is arranged on is increased possibly leading to a reduced parasitic capacity which in turn may reduce losses.

According to an exemplary embodiment of the electronic device the die comprising a second switched terminal wherein the second switched terminal is electrically connected to the carrier body.

In particular, the second switched terminal may be a source terminal in case the die forms or comprises a transistor. In particular, in case of the carrier body is part of a lead frame (e.g. the die pad) the second switched terminal may be electrically connected to a die pad (area) of the lead frame. For example, the switched terminal (e.g. drain) may be formed or arranged on a first surface of the die and the second switched terminal (e.g. source) may be formed or arranged on a second surface opposite to the first surface.

According to an exemplary embodiment of the electronic device the second switched terminal is electrically connected to the carrier body by one element out of the group consisting of: a bond wire; a plurality of bond wires; bond clip; and a bond ribbon.

The use of a plurality of bond wires or more particularly of a bond ribbon or clip may enlarge a heat conducting path and thus increase a heat transmission or conduction from the die to the carrier body. It should be noted that the heat transmission from the source contact to the environment may be smaller than in case the die would be mounted on the carrier body itself. However, due to reduced losses the waste heat generation is smaller as well so that an increasing of the temperature of the electronic device may only be small.

According to an exemplary embodiment of the electronic device the die is attached to the one of the plurality of pins by a process selected out of the group consisting of: soldering; bonding; adhesion process; and sintering.

In particular, the soldering may be a diffusion soldering or a soft soldering, while the bonding or bonding process may be an eutectic bonding process. For example, the sintering may be a silver sintering process. It should be noted that the adhesion process may use an (electrically conductive) adhesion agent. For example, the die (in particular, the switched terminal) may be attached or mounted onto the one pin directly or via a redistribution layer or wire bonding (e.g. aluminum wedge and/or copper ball). Furthermore, other terminals (like a gate terminal and/or source terminal) of the die may be electrically redistributed by wire bonding to other pins or the carrier body.

According to an exemplary embodiment of the electronic device the die comprises a control terminal electrically connected to a further one of the plurality of pins.

In particular, the control terminal (e.g. a gate terminal or contact of a FET) may be electrically connected by a bond wire, bond ribbon or bond clip.

According to an exemplary embodiment the electronic device further comprises an electronic chip arranged on the carrier body.

In particular, a plurality of electronic chips (e.g. integrated chips or dies) may be arranged on the carrier body (e.g. a die pad of a lead frame). The electronic chip(s) may provide for additional functionalities of the electronic device.

According to an exemplary embodiment the electronic device further comprises an encapsulation at least partially encapsulating the carrier body and the plurality of pins.

In the following exemplary embodiments of the method of manufacturing an electronic device are described. However, the features and elements described with respect to these embodiments can be combined with exemplary embodiments of the electronic device.

According to an exemplary embodiment the method further comprises electrically connecting a further switched terminal to the carrier body.

In particular, the electrical connecting of the further switched terminal (e.g. a source terminal or contact) may be performed by bond wire(s), bond ribbon(s) and/or bond clip(s).

According to an exemplary embodiment of the method the attaching of the die may be performed by a process selected out of the group consisting of: soldering; bonding; adhesion process; and sintering.

According to an exemplary embodiment the method further comprises electrically connecting a switch terminal to a further pin of the plurality of pins.

In particular, the switch terminal or control terminal may be a gate terminal of a field effect transistor.

In the following specific embodiments of the electronic device and the method of manufacturing an electronic device will be described in more detail with respect to the figures.

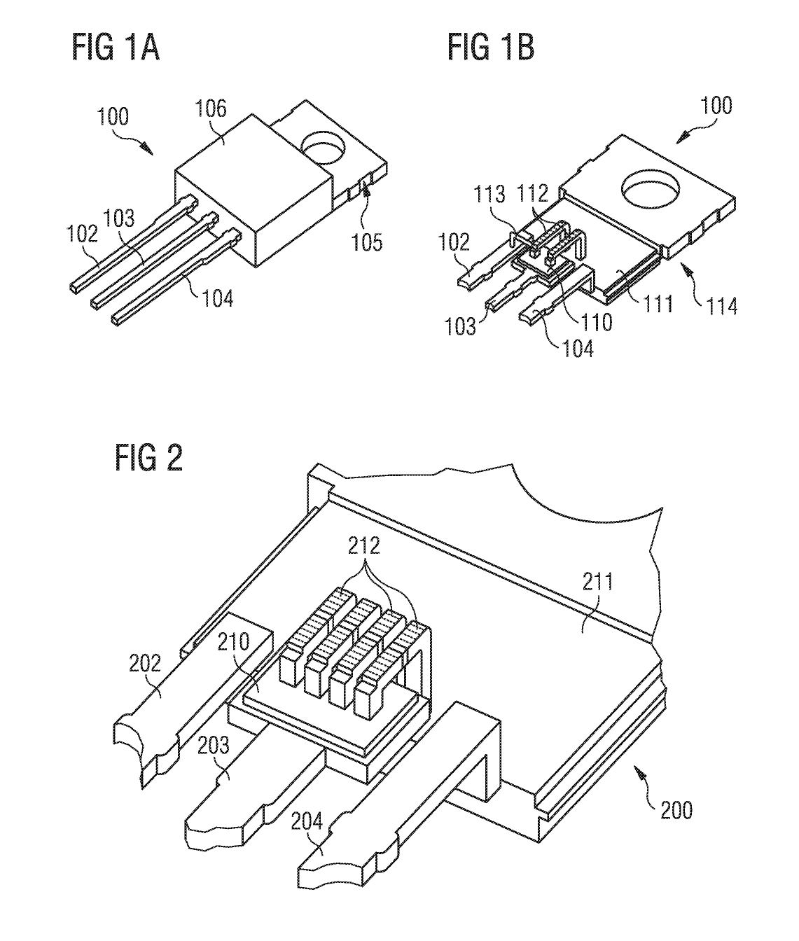

FIGS. 1A and 1B schematically show a detail of an electronic device 100 according to an exemplary embodiment. In particular, FIG. 1A shows that the electronic device 100 comprises a lead frame comprising a plurality of leads or pins 102, 103 and 104, and a mounting area 105 (which is configured to be mounted to an external structure, e.g. an external heat sink or external mounting structure). Furthermore, an encapsulation 106 is depicted in FIG. 1A encapsulating a die not shown in FIG. 1A. FIG. 1B shows the electronic device 100 of FIG. 1A having the encapsulation removed. Due to the removing of the encapsulation the die 110 can be seen. The die 110 is directly mounted or attached to one 103 of the plurality of leads of the lead frame 114. According to the shown embodiment the die is a (power) transistor comprising a drain terminal or drain contact on one surface (facing down in FIG. 1B) which is mounted to the one pin. On the opposite surface (upper surface in FIG. 1B) of the die a source terminal or contact is formed.

The source contact is connected to a die pad (or carrier body) 111 of the lead frame by two bond wires or clips 112. These bond wires 112 form an electrical contact as well as a thermal contact between the source terminal and the die pad 111, which form a kind of heat sink (and which in turn may as well be mounted to an external heat sink). In addition the die pad 111 is electrically connected to another one 104 of the lead. In particular, the another lead or pin 104 is integrally formed (not cut) from the die pad 111. In addition, a gate terminal or contact of the die is electrically connected to a further lead or pin 103 of the plurality of leads, e.g. via a bond wire or clip 113. It should be noted that the one pin 103 and the further pin 102 are electrically disconnected or isolated from the die pad 111.

In FIG. 1B it can be seen that the die pad 111 and the leads 102, 103 and 104 are formed on different levels. In particular, the leads 102, 103 and 104 are arranged on a common level or plane (lying higher in the FIG. 1B) and the die pad and the mounting area of the lead frame are arranged on a different level or plane. For clarity reasons it should be noted that lead 102 forms a gate contact, lead 103 forms a drain contact and the lead 104 forms a source contact of the electronic device 100.

FIG. 2 schematically shows a detail of an electronic device 200 according to an exemplary embodiment. In general the electronic device 200 is similar to the one shown in FIG. 1B. However, instead of only two bond wires or bond clips as shown in FIG. 1B four bond wires or clips 212 electrically and thermally connecting a source terminal of a die 211 attached to a pin 203 via a drain contact with a die pad 211. Thus, a heat transfer from the die 210 to the die pad 211 may be increased.

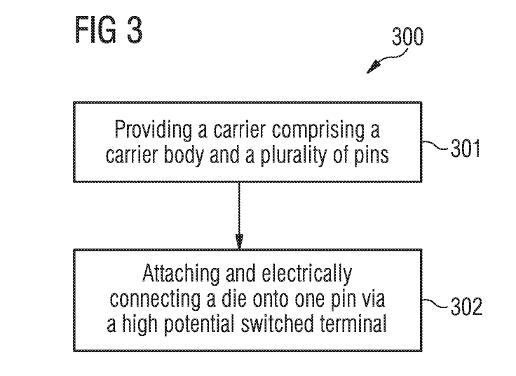

FIG. 3 illustrate a flowchart 300 of a method manufacturing an electronic device according to an exemplary embodiment. In a first step (301) a carrier comprising a carrier body and a plurality of pins is provided. In a further step (302) a die comprising a switched terminal is attached and electrically connecting onto one of the plurality of pins, wherein the attaching is performed in such a way that a high electrical potential is connectable to the switched terminal.

Optional further steps may be to electrically connect a further switched terminal to the carrier body and/or to electrically connect a switch terminal to a further pin of the plurality of pins.

It should also be noted that the term “comprising” does not exclude other elements or features and the “a” or “an” does not exclude a plurality. Also elements described in association with different embodiments may be combined. It should also be noted that reference signs shall not be construed as limiting the scope of the claims. While the invention has been particularly shown and described with reference to specific embodiments, it should be understood by those skilled in the art that various changes in form and detail may be made therein without departing from the spirit and scope of the invention as defined by the appended claims. The scope of the invention is thus indicated by the appended claims and all changes which come within the meaning and range of equivalency of the claims are therefore intended to be embraced.

What is claimed is:

1. An electronic device comprising:
a carrier body;
a plurality of pins,
a die comprising a switched terminal;
wherein the switched terminal is attached onto and electrically connected to one of the plurality of pins; and
wherein the die is configured in such a way that the switched terminal is electrically connected to a high electrical potential.

2. The electronic device according to claim 1, wherein the carrier body is part of a lead frame comprising a die pad and a plurality of leads, wherein the pins are formed by the plurality of leads and the carrier body is formed by the die pad.

3. The electronic device according to claim 1, wherein the carrier body and the plurality of pins are arranged on different levels.

4. The electronic device according to claim 1, wherein the die comprising a second switched terminal wherein the second switched terminal is electrically connected to the carrier body.

5. The electronic device according to claim 4, wherein the second switched terminal is electrically connected to the carrier body by one element out of the group consisting of:
a bond wire;
a plurality of bond wires;
bond clip; and
a bond ribbon.

6. The electronic device according to claim 1, wherein the die is attached to the one of the plurality of pins by a process selected out of the group consisting of:
soldering;
bonding;
adhesion process; and
sintering.

7. The electronic device according to claim 1, wherein the die comprises a control terminal electrically connected to a further one of the plurality of pins.

8. The electronic device according to claim 1, further comprising an electronic chip arranged on the carrier body.

9. The electronic device according to claim 1, further comprising an encapsulation at least partially encapsulating the carrier body and the plurality of pins.

10. An electronic device comprising:
a field effect transistor comprising a drain terminal;
a lead frame comprising a die pad and a plurality of leads;
wherein the drain terminal is electrically connected to and attached onto at least one of the plurality of leads.

11. A method of manufacturing an electronic device, the method comprising:
providing a carrier comprising a carrier body and a plurality of pins;
attaching and electrically connecting a die comprising a switched terminal onto one of the plurality of pins, wherein the attaching is performed in such a way that a high electrical potential is connectable to the switched terminal.

12. The method according to claim 11, further comprising electrically connecting a further switched terminal to the carrier body.

13. The method according to claim 11, wherein the attaching of the die may be performed by a process selected out of the group consisting of:
soldering;
bonding;
adhesion process; and
sintering.

14. The method according to claim 11, further comprising electrically connecting a switch terminal to a further pin of the plurality of pins.
